(19) United States
(12) Patent Application Publication
(10) Pub. No.: US 2011/0084375 A1
(43) Pub. Date: Apr. 14, 2011

(54) SEMICONDUCTOR DEVICE PACKAGE WITH INTEGRATED STAND-OFF

(75) Inventors: Poh Leng Eu, Petaling Jaya (MY); Kai Yun Yow, Petaling Jaya (MY)

(73) Assignee: FREESCALE SEMICONDUCTOR, INC, Austin, TX (US)

(21) Appl. No.: 12/577,722

(22) Filed: Oct. 13, 2009

(51) Int. Cl. H01L 23/498; H01L 21/56

(52) U.S. Cl. 257/690; 438/124; 257/E23.068; 257/E21.502

(57) ABSTRACT

A semiconductor device includes a substrate having first and second major surfaces and conductive traces, and solder balls attached to the second major surface of the substrate. A semiconductor die including an integrated circuit (IC) is attached to one of the major surfaces of the substrate. The IC is electrically connected to the solder balls by the conductive traces. The substrate includes an integrally molded stand-off feature that prevents the solder balls near the corners and the sides of the substrate from being knocked off during handling. The stand-off feature also maintains a predetermined distance between the substrate and a printed circuit board (PCB) when the substrate is attached to the PCB, and then a reflow process is performed. The stand-off feature also prevents open connections between the solder balls and the PCB that may be caused by warping of the PCB or the weight of the semiconductor die. The semiconductor device may include a stiffener ring attached to the second major surface of the substrate and surrounding the conductive balls.

### BACKGROUND OF THE INVENTION

The present invention relates generally to semiconductor device packaging, and more particularly to a packaged semiconductor device with an integrated stand-off.

A semiconductor die includes an integrated circuit formed in Silicon. One way of connecting the integrated circuit to other circuits or electronic devices is to attach the die to one side of a substrate, the other side of the substrate having a plurality of conductive balls that allow the device to be attached to a printed circuit board (PCB). The conductive balls are often arranged in an array, and thus this type of device is called a ball grid array (BGA). FIG. 1 is a cross-sectional side view of a conventional BGA device 10. The BGA device 10 includes a substrate 12 and a plurality of conductive balls 14.

During assembly, the balls 14 in the outer rows and near the corners of the substrate 12 can fall off, for instance due to improper handling or impact with a hard surface, especially if lead free materials are used. FIG. 2A is a bottom view of the BGA device 10 in which a few of the balls 14 have fallen off, leaving spaces 16. FIG. 2B is a greatly enlarged view of one of the spaces 16 where there is a missing ball 14.

Another problem sometimes encountered is that when the a BGA device is connected to a printed circuit board (PCB), if the device is heavy, relatively speaking, after the device has been attached to the PCB, there is not a sufficient clearance between the PCB and the device.

FIG. 3A shows another conventional BGA device 20 comprising a die 22 attached to a substrate 24. The substrate 24 includes a plurality of conductive balls 26 for attaching the device 20 to a PCB. FIG. 3B shows the device during attachment to a PCB 28 during a surface mount assembly process. FIG. 3C shows the device 20 after a reflow process in which the balls 26 are connected to pads on the PCB 28. As can be seen in FIG. 3B, the substrate 24 is relatively close to the PCB 28 and thus there is a low stand-off height, which is indicated at 30.

FIG. 4A shows another type of conventional BGA device 40 known as a glob top device. The glob top device 40 comprises a substrate 42 having an array of conductive balls 44 attached its bottom surface and a die (not shown) that also is attached to the bottom surface of the substrate 42. The die is often surrounded with a glob of epoxy type material 46. FIG. 4B shows the glob top device 40 during attachment to a PCB 48 during a surface mount assembly process. FIG. 4C shows the device 40 after a reflow process in which the package weight and the glob top have caused an open joint (no connection) on the left side of the device.

Yet another problem sometimes experienced with BGA devices is substrate warpage, such as when “green” materials are used to form the substrate. FIG. 5 is a cross-sectional side view of a device 50 comprising a die 52 attached to a top surface of a substrate 54. The substrate 54 has a plurality of conductive balls 56 attached to its bottom surface. The substrate 54 is attached to a PCB 58 by way of the balls 56, typically with a reflow process. In this example, the substrate 54 is warped, which can cause open center joints, indicated at 60.

It would be advantageous to have a BGA device that is less susceptible to having missing balls due to improper handling, insures adequate stand-off, and accommodates for warping.

### BRIEF DESCRIPTION OF THE DRAWINGS

The invention, together with objects and advantages thereof, may best be understood by reference to the following description of the presently preferred embodiments together with the accompanying drawings. In the drawings, like numerals are used for like elements throughout.

FIG. 1 illustrates an enlarged cross-sectional side view of a conventional BGA substrate;

FIG. 2A is a bottom view of the BGA substrate shown in FIG. 1;

FIG. 2B is a greatly enlarged partial bottom view photograph of the BGA substrate shown in FIG. 1;

FIG. 3A is an enlarged cross-sectional side view of another conventional BGA type semiconductor device;

FIG. 3B is an enlarged cross-sectional side view of the BGA type semiconductor device of FIG. 3A on a PCB;

FIG. 3C is an enlarged cross-sectional side view of the BGA type semiconductor device of FIG. 3B after a reflow process;

FIG. 4A is a cross-sectional side view of a conventional glob top type BGA device;

FIG. 4B shows the glob top type BGA device of FIG. 4A mounted to a PCB;

FIG. 4C shows the glob top device of FIG. 4B after a reflow process;

FIG. 5 is a cross-sectional side view illustrating substrate warpage in yet another conventional BGA device;

FIG. 6 is a cross-sectional side view of a substrate for a BGA device in accordance with an embodiment of the present invention;

FIG. 7 is a cross-sectional side view of a substrate for a glob top BGA device in accordance with an embodiment of the present invention;

FIGS. 8A-8C are bottom plan views of various alternative embodiments of a substrate in accordance with the present invention;

FIG. 8D is a top plan view of another alternative embodiment of a substrate in accordance with the present invention;

FIGS. 9A-9D illustrate the assembly of a substrate in accordance with another embodiment of the present invention;

FIG. 10 illustrates a glob top device in accordance with an embodiment of the present invention attached to a PCB;

FIG. 11 illustrates a BGA device in accordance with an embodiment of the present invention attached to a PCB; and

FIG. 12 illustrates another BGA device in accordance with an embodiment of the present invention attached to a PCB.

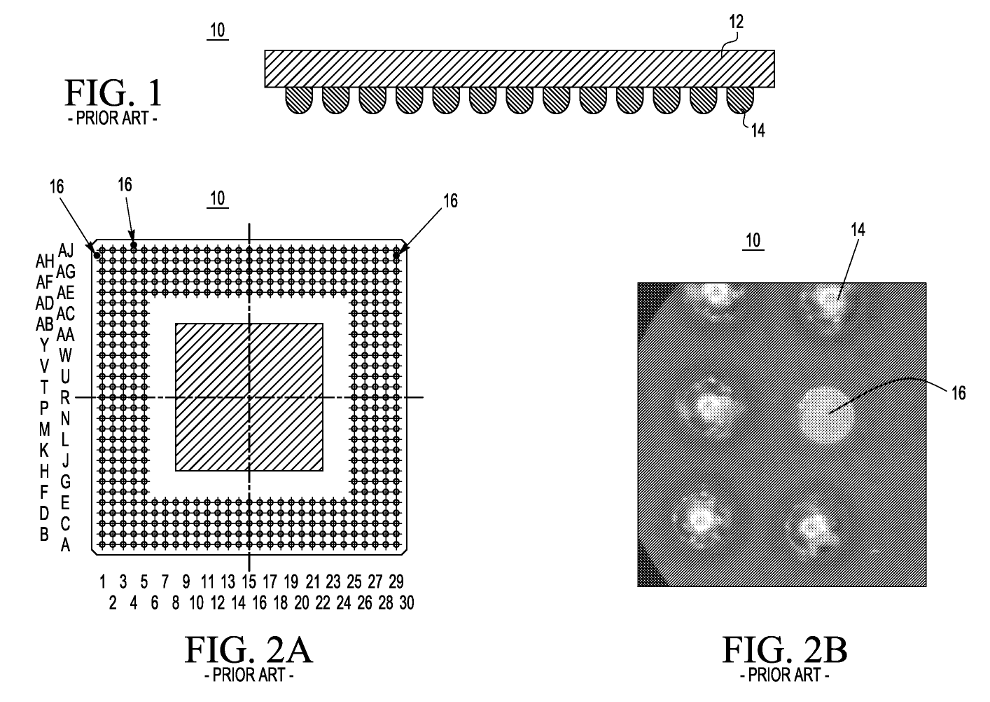

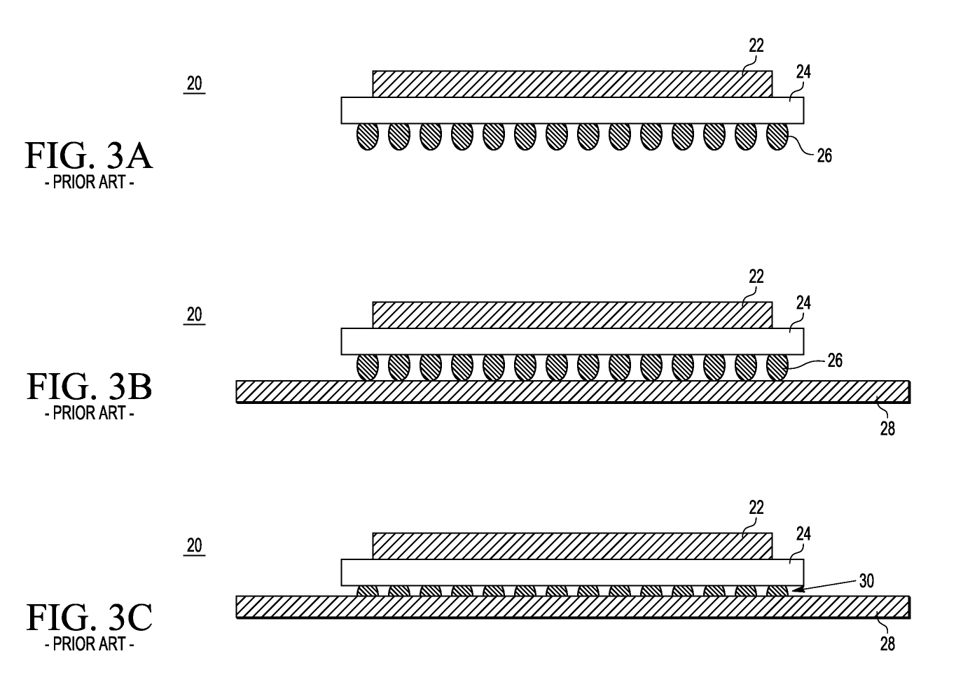

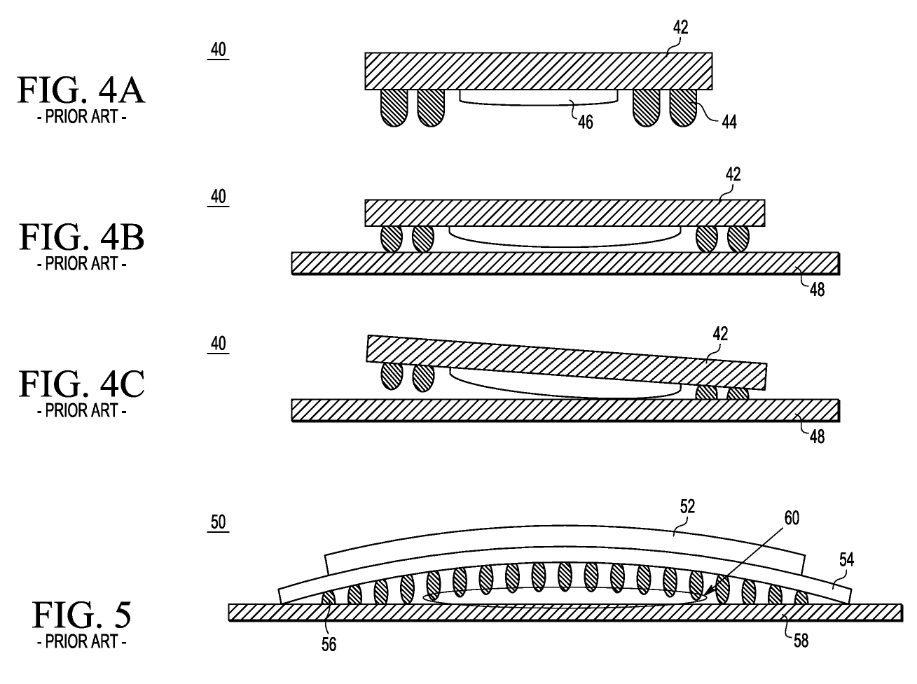

### DETAILED DESCRIPTION OF THE INVENTION

In one embodiment, the present invention provides a semiconductor device including a substrate having a first major surface and a second major surface, and a plurality of conductive traces located therein. A semiconductor die including an integrated circuit (IC) is attached to one of the major surfaces of the substrate. A plurality of conductive balls is attached to the second major surface of the substrate. The conductive traces of the substrate electrically connect the IC with the conductive balls. The substrate includes an integral stand-off that projects perpendicularly downward from the second major surface of the substrate. The stand-off has a length (or height) that is less than a diameter of the conductive balls.

The purpose of the stand-off is to protect conductive balls located near a perimeter and at the corners of the substrate from being knocked off during handling. The stand-off also insures that the second major surface of the substrate is maintained at a predetermined distance from a board to which it is later attached. Yet another function of the stand-off is to prevent open joints, such as may be caused by a warped substrate.

In another embodiment, the present invention provides a method of assembling a semiconductor device, including the steps of:

fabricating a substrate having first and second major surfaces and a plurality of conductive traces;

molding the substrate to form a stand-off that projects perpendicularly downward from the second major surface of the substrate;

attaching a semiconductor die including an IC to one of the major surfaces of the substrate; and

attaching a plurality of conductive balls to the second major surface of the substrate, wherein the integrated circuit is electrically connected to the conductive balls by the conductive traces.

Referring now to FIG. 6, an enlarged, cross-sectional side view of a substrate 60 in accordance with an embodiment of the present invention is shown. The substrate 60 has a first major surface 62 and a second major surface 64, and a plurality of conductive traces located therein (not shown). A plurality of conductive balls is attached to the second major surface 64 of the substrate 60. The solder balls 66 are in electrical contact with the conductive traces of the substrate 60. A semiconductor die (not shown) including an integrated circuit (IC) may be attached to the first major surface 62 of the substrate 60, in which case the IC is electrically connected to the conductive balls 66 by way of the conductive traces of the substrate 60. Substrates, semiconductor die, and conductive balls are well known to those of skill in the art and further description is not necessary for a full understanding of the present invention. For example, the die may comprise a CPU (central processing unit), a memory, or any other integrated circuit, and the conductive balls may comprise C4 (Controlled, Collapse, Chip, Connection) solder balls.

The substrate 60 also includes an integral stand-off 68 that projects perpendicularly downward from the second major surface 62. The stand-off 68 has a length (or height) that is less than a diameter of the conductive balls 66 such that the balls 66 extend beyond a level of the stand-off 68. In the preferred embodiment of the invention, the stand-off 68 is formed by a molding process. The molding compound is first preheated prior to its loading into the molding chamber. After pre-heating, the molding compound is forced by a hydraulic plunger into the pot where it reaches melting temperature and becomes fluid. The plunger then continues to force the now fluid molding compound into runners of the mold chase. The runners serve as canals where the fluid molding compound travels until it reaches cavities, which contain the leadframes/substrates for encapsulation.

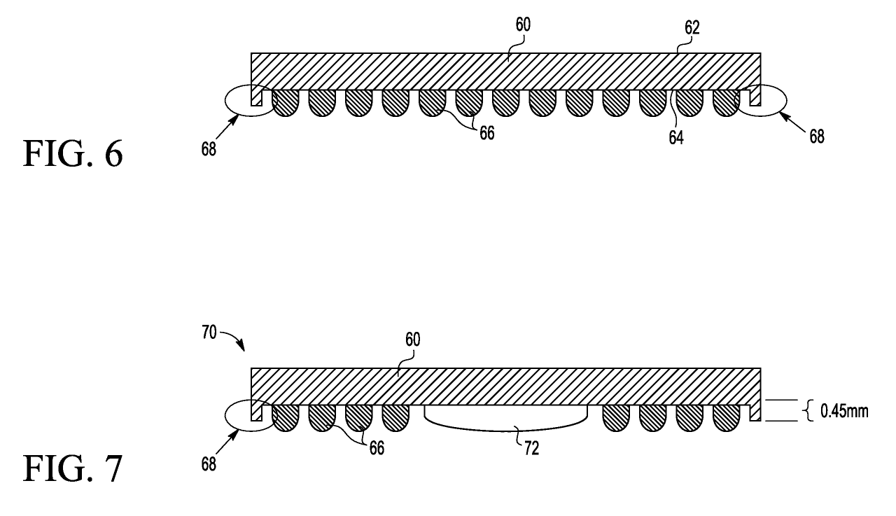

FIG. 7 is an enlarged, cross-sectional side view of a semiconductor device 70 in accordance with another embodiment of the present invention. The semiconductor device 70 includes the substrate 60 with first and second major surfaces 62 and 64, the conductive traces (not shown), the conductive balls 66, and the stand-off 68. A semiconductor die (not shown) also is attached to the second major surface 64 of the substrate 60. The semiconductor die is encapsulated or covered with a protective material 72. The protective material 72 may be an epoxy, or resin, or mold compound, as is known to those of skill in the art. The manner in which the protective material 72 covers the die is typically termed a glob top. The IC of the semiconductor die is in electrical contact with the conductive balls 66 by way of the conductive traces of the substrate 60.

In this embodiment, the glob height, i.e., the distance the protective material 72 extends from the second major surface 64 of the substrate 60 is about 0.455 mm, while the conductive balls 66 have a height (diameter) of about 0.538 mm. The stand-off 68 extends downwardly and perpendicularly to the second major surface a distance of about 0.45 mm. In other embodiments of the invention, the stand-off 68 has a length of between 0.35 mm and 0.50 mm and the conductive balls 66 have a diameter of between 0.40 mm and 0.55 mm. As is known to those of skill in the art, when the semiconductor device 70 is attached to another substrate or printed circuit board (PCB), a reflow process is performed in which the conductive balls 66 are heated and melt, and thus the diameter of the balls is decreased, but preferably the ball height remains greater than or equal to the length of the stand-off.

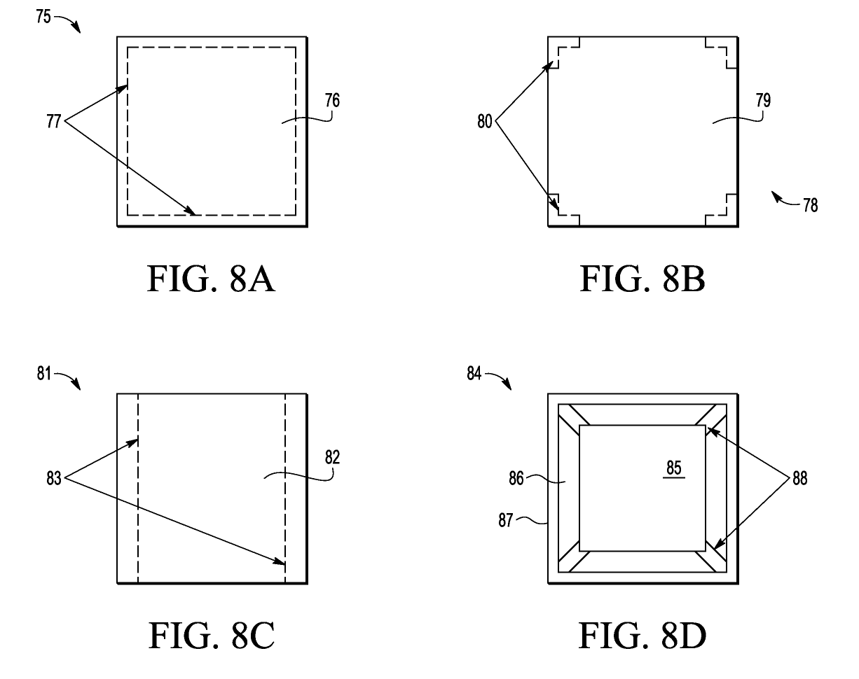

Referring now to FIGS. 8A-8C, bottom plan views of three alternative embodiments of the present invention are shown. FIG. 8A shows a substrate 75 having a second major surface 76 to which conductive balls (not shown) are attached. The substrate 75 has a generally rectangular shape. A stand-off 77 is formed along the four sides of the substrate 75. FIG. 8B shows a substrate 78 having a second major surface 79 to which conductive balls (not shown) are attached. The substrate 78 has a generally rectangular shape. A stand-off 80 is formed along two opposing sides of the substrate 78. FIG. 8C shows a substrate 81 having a second major surface 82 to which conductive balls (not shown) are attached. The substrate 81 has a generally rectangular shape. A stand-off 83 is formed at the four corners of the substrate 81. In each of these embodiments, the stand-offs 77, 80 and 83 are formed by molding the respective substrates 75, 78 and 81. The embodiments shown in FIGS. 8A-8C are not all of the ways in which the stand-off may be arranged.

FIG. 8D is a top plan view of an electronic device 84 in accordance with yet another embodiment of the present invention. FIG. 8D shows an integrated circuit 85 attached to a substrate 86. The substrate 86 has an integral, molded stand-off 87 formed along its four sides or perimeter. In this embodiment, the device 84 also includes ribs 88 that extend from the stand-off 87 to the integrated circuit 85 at the four corners of the device 84. The ribs 88 reinforce the stand-off 87, thereby providing additional strength to the device 84.

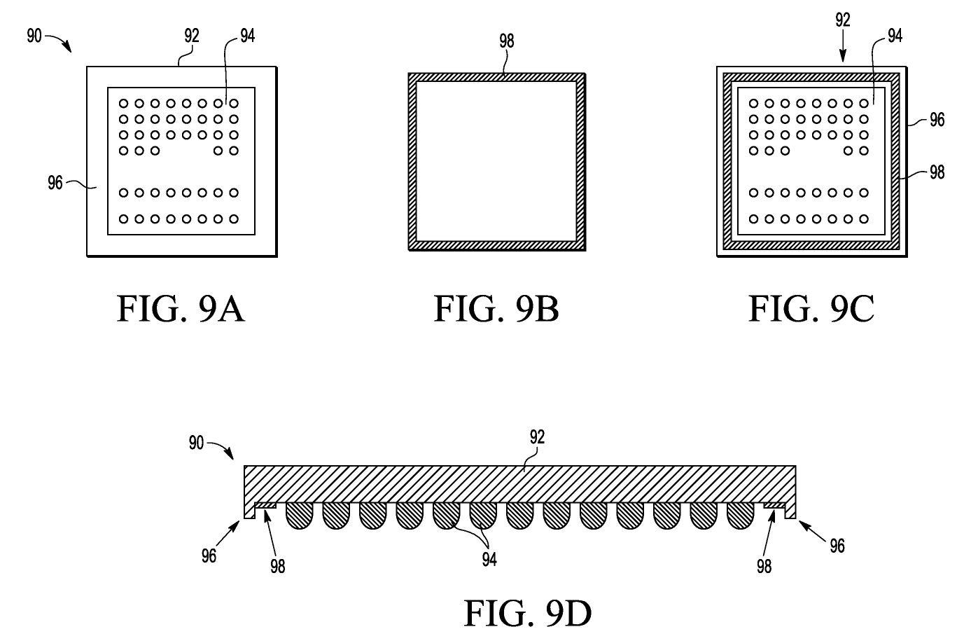

FIG. 9A is a bottom plan view of a semiconductor device 90 in accordance with an embodiment of the present invention. The semiconductor device 90 includes a substrate 92 have an array of conductive balls 94 on a second major surface (bottom side) thereof. A stand-off 96 surrounds the array of conductive balls 94. That is, the stand-off in this embodiment runs along all four sides of the substrate 92. FIG. 9B is a top plan view of a stiffener ring 98. The stiffener ring 98 is has the same shape as the substrate 92 but a slightly smaller dimension so that the ring 98 will fit between the array of conductive balls 94 and the stand-off 96. FIG. 9C is a bottom plan view of the substrate 92 with the stiffener ring 98 attached to the second major surface between the array of conductive balls 94 and the stand-off 96. The stiffener ring 98 is formed of a generally stiff material such as copper. The ring 98 may be attached to the substrate in a variety of ways, such as by tacking, gluing with an adhesive material, or by plating the ring 98 to the substrate 92. The ring 98 aids in limiting warping of the substrate 92. FIG. 9D is a cross-sectional side view of the semiconductor device 90, showing the substrate 92, the conductive balls 94, the stand-off 96, and the stiffener 98.

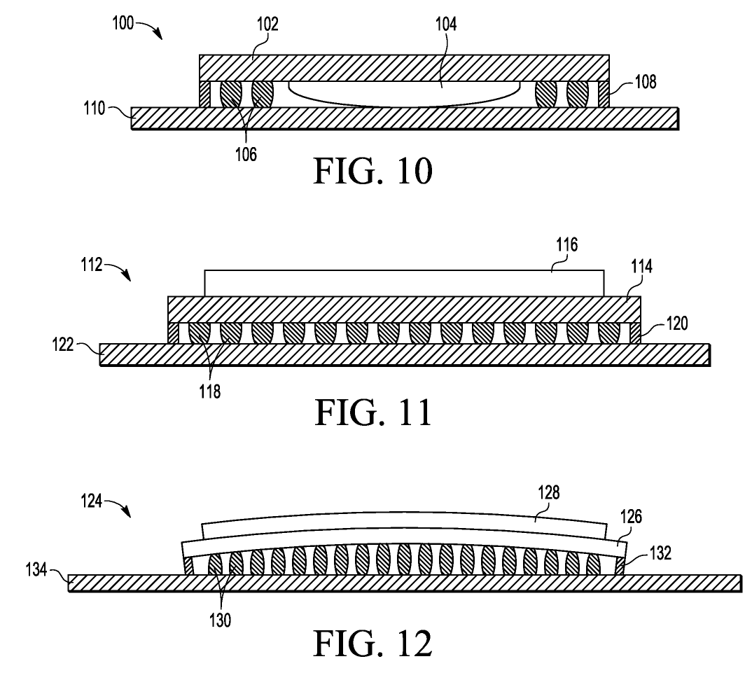

Referring now to FIGS. 10-12, cross-sectional side view of three embodiments of a semiconductor device attached to a PCB, in accordance with the present invention. FIG. 10 shows a semiconductor device 100 including a substrate 102, a semiconductor die attached to a bottom (or second) side of the substrate 102 and encapsulated with a protective material 104, and a plurality of conductive balls 106. The substrate 102 also includes an integral stand-off 108. In the embodiment shown, the bottom side of the substrate 102 is attached to a PCB 110 by way of the conductive balls 106. As is known by those of skill in the art, a reflow process is performed to attach the balls 106 to the PCB 110. FIG. 10 shows the semiconductor device 100 attached to the PCB 110 after a reflow process has been performed. Note that the stand-off 108 prevents open connections between the conductive balls 106 and the PCB 110, and maintains a predetermined distance between the bottom side of the substrate 102 and the printed circuit board 110.

FIG. 11 is a cross-sectional side view of another embodiment of a semiconductor device 112 in accordance with the present invention. The semiconductor device 112 includes a substrate 114, a semiconductor die 116 attached to first or top side of the substrate 114, and a plurality of conductive balls 118 attached to the bottom or second side of the substrate 114. The die 116 is electrically connected to the conductive balls 118 by way of conductive traces in the substrate 114. The semiconductor device 112 also includes a stand-off 120 that is integral with the substrate 114. The semiconductor device 112 is attached to a PCB 122 and the balls 118 are electrically connected to the PCB with a reflow process. Note that despite the weight of the substrate 114 and the die 116, the stand-off 120 insures that the substrate 114 is maintained at a predetermined distance from the PCB 122.

FIG. 12 is a cross-sectional side view of another embodiment of a semiconductor device 124 in accordance with the present invention. The semiconductor device 124 is similar to the semiconductor device 112 of FIG. 11 and includes a substrate 126, a semiconductor die 128 attached to first or top side of the substrate 126, and a plurality of conductive balls 128 attached to the bottom or second side of the substrate 126. The die 128 is electrically connected to the conductive balls 130 by way of conductive traces in the substrate 126. The semiconductor device 124 also includes a stand-off 132 that is integral with the substrate 126. However, the substrate 126 differs in that in this embodiment it is fabricated using environmentally friendly or so-called “green” materials. Such materials include halide free core materials and a halide free solder mask. As previously discussed, substrates made with green materials are more apt to warp then conventional substrates. Thus, as shown in FIG. 12, even if the substrate 126 is warped, when a reflow process is performed to attach the semiconductor device 124 to a PCB 134 the stand-off 132 exerts an upward pressure at the ends of the substrate 132, which prevents excessive warping from causing open joints (see FIG. 5).

As previously discussed, the present invention also includes a method of assembling a semiconductor device, where the semiconductor device includes semiconductor die having an IC, a substrate with conductive traces and a plurality of conductive balls attached to one side of the substrate. The IC is electrically connected to the balls via the conductive traces. The method includes the steps of fabricating the substrate, and molding the substrate so that a stand-off is formed at least at the four corners of the substrate. Alternatively, the substrate is molded so that the stand-off runs along either two sides of the substrate or along all four sides of the substrate. A stiffener ring may be attached to the substrate between the stand-off and the conductive balls. The die may be attached to either a top or bottom side of the substrate (also referred to herein as the first and second major surfaces of the substrate). The semiconductor device may be attached to a PCB and a reflow operation performed to affix the balls to the PCB. The stand-off prevents open connections between the conductive balls and the printed circuit board. The stand-off also protects the conductive balls from being knocked-off of the substrate by mishandling of the substrate.

While embodiments of the invention have been described and illustrated, it will be understood by those skilled in the technology concerned that many variations or modifications in details of design or construction may be made without departing from the present invention.

1. A semiconductor device, comprising:
a substrate having a first major surface and a second major surface, wherein the substrate has a plurality of conductive traces located therein;
a semiconductor die attached to one of the major surfaces of the substrate, wherein the semiconductor die includes an integrated circuit formed therein; and
a plurality of conductive balls attached to the second major surface of the substrate, wherein the conductive traces of the substrate electrically connect the integrated circuit with the conductive balls, and
wherein the substrate includes an integral stand-off that projects perpendicularly downward from the second major surface of the substrate and wherein the stand-off has a length that is less than a diameter of the conductive balls.

2. The semiconductor device of claim 1, wherein the stand-off is formed by molding of the substrate.

3. The semiconductor device of claim 2, wherein the substrate is generally rectangular and the stand-off is formed at least at the four corners of the substrate.

4. The semiconductor device of claim 2, wherein the substrate is generally rectangular and the stand-off is formed along at least two sides of the substrate.

5. The semiconductor device of claim 4, wherein the stand-off is formed along four sides of the substrate.

6. The semiconductor device of claim 4, wherein the second major surface of the substrate is attached to a printed circuit board by way of the conductive balls and wherein after a reflow process, the stand-off prevents open connections between the conductive balls and the printed circuit board.

7. The semiconductor device of claim 6, wherein the stand-off maintains a predetermined distance between the second major surface of the substrate and the printed circuit board.

8. The semiconductor device of claim 2, wherein the die is attached to the first major surface of the substrate.

9. The semiconductor device of claim 2, wherein the die is attached to a central area of the second major surface of the substrate and is surrounded by the conductive balls, and wherein the die is encapsulated with a protective material.

10. The semiconductor die of claim 2, further comprising a ring formed of a generally stiff material, wherein the ring is attached to the second major surface of the substrate and is disposed between the conductive balls and the stand-off.

11. The semiconductor device of claim 10, wherein the ring comprises copper.

12. The semiconductor device of claim 10, wherein the ring is tacked to the substrate.

13. The semiconductor device of claim 10, wherein the ring is plated to the substrate.

14. The semiconductor device of claim 2, wherein the substrate comprises green materials.

15. The semiconductor device of claim 2, wherein the stand-off has a length of between 0.35 mm and 0.50 mm and the conductive balls have a diameter of between 0.40 mm and 0.55 mm.

16. The semiconductor device of claim 1, wherein the stand-off prevents conductive balls near to a periphery of the substrate from being dislodged.

17. A method of assembling a semiconductor device, comprising:
fabricating a substrate including a plurality of conductive traces, wherein the substrate has a first major surface and a second major surface;
molding the substrate to form a stand-off that projects perpendicularly downward from the second major surface of the substrate;
attaching a semiconductor die including an integrated circuit to one of the major surfaces of the substrate; and
attaching a plurality of conductive balls to the second major surface of the substrate, wherein the integrated circuit is electrically connected to the conductive balls by the conductive traces.

18. The method of assembling a semiconductor device of claim 17, further comprising attaching a ring formed of a stiff material to the second major surface of the substrate, wherein the ring surrounds the plurality of conductive balls.

19. The method of assembling a semiconductor device of claim 17, further comprising attaching the die to the second major surface of the substrate and encapsulating the die with a protective material.

20. The method of assembling a semiconductor device of claim 19, further comprising:
attaching the second major surface of the substrate to a printed circuit board by way of the conductive balls; and
performing a reflow process to facilitate electrical connection of the conductive balls to the printed circuit board, wherein the stand-off prevents open connections between the conductive balls and the printed circuit board.
